(19) United States
(12) Patent Application Publication
(10) Pub. No.: US 2011/0291526 A1
(43) Pub. Date: Dec. 1, 2011

(54) PIEZOELECTRIC STACK COMPRESSION GENERATOR

(75) Inventors: Haim ABRAMOVICH, Nesher (IL); Charles Milgrom, Moshav Aminadav (IL); Eugeny Harash, Haifa (IL); Lucy Edery-Azulay, Haifa (IL); Uri Amit, Raanana (IL)

(73) Assignee: Innowattech Ltd., Haifa (IL)

(21) Appl. No.: 12/789,007

(22) Filed: May 27, 2010

(51) Int. Cl. H02N 2/18; H01L 41/053; F03G 7/08; H01L 41/083

(52) U.S. Cl. 310/339; 310/366; 310/354; 290/1 R

(57) ABSTRACT

A stack of piezoelectric elements, in the form of an elongated rod divided in to segments, for generating electric energy in response to compressive stress is provided comprising: piezoelectric elements stacked one on top of the other such that electrodes of same polarity of adjacent disks are touching A holding structure, such as a screw holds the piezoelectric elements together between a top and a bottom end pieces which transfer mechanical compressive stress to the elements in the stack. The holding structure accepts shear stresses, provides preloading stress on the stack and prevents buckling of the stack under pressure. A recess in the end piece, deeper than the head of the screw, ensures that load placed on the stack will compress the piezoelectric elements and not on the screw.

### FIELD OF THE INVENTION

The present invention relates to an energy harvesting apparatus having stack piezoelectric elements, and system, method and applications for implementation of said apparatus.

### BACKGROUND OF THE INVENTION

Piezoelectricity is the ability of certain materials to develop an electrical charge proportional to an applied mechanical stress. The converse effect can also be seen in these materials where strain is developed proportional to an applied electrical field. The Curie's originally discovered it in the 1880's. Piezoelectric materials are the most well known active material typically used for transducers as well as in adaptive structures. Mechanical compression or tension on a poled piezoelectric element changes the dipole moment, creating a voltage. Compression along the direction of polarization, or tension perpendicular to the direction of polarization, generates voltage of the same polarity as the poling voltage. Tension along the direction of polarization, or compression perpendicular to the direction of polarization, generates a voltage with polarity opposite that of the poling voltage. These actions are generator actions—the piezoelectric element converts the mechanical energy of compression or tension into electrical energy. This behavior is used in fuel-igniting devices, solid state batteries, force-sensing devices, and other products. Values for compressive stress and the voltage (or field strength) generated by applying stress to a piezoelectric ceramic element are linearly proportional up to a material-specific stress. The same is true for applied voltage and generated strain.

The review article “Advances In Energy Harvesting Using Low Profile Piezoelectric Transducers”; by Shashank Priya; published in J Electroceram (2007) 19:165-182; provides a comprehensive coverage of the recent developments in the area of piezoelectric energy harvesting using low profile transducers and provides the results for various energy harvesting prototype devices. A brief discussion is also presented on the selection of the piezoelectric materials for on and off resonance applications.

The paper “On Low-Frequency Electric Power Generation With PZT Ceramics”; by Stephen R. Platt, Shane Farritor, and Hani Haider; published in IEEE/ASME Transactions On Mechatronics, VOL. 10, NO. 2, April 2005; discusses the potential application of PZT based generators for some remote applications such as in vivo sensors, embedded MEMS devices, and distributed networking. The paper points out that developing piezoelectric generators is challenging because of their poor source characteristics (high voltage, low current, high impedance) and relatively low power output.

The article “Energy Scavenging for Mobile and Wireless Electronics”; by Joseph A. Paradiso and Thad Starner; Published by the IEEE CS and IEEE ComSoc, 1536-1268/05/; reviews the field of energy harvesting for powering ubiquitously deployed sensor networks and mobile electronics and describers systems that can scavenge power from human activity or derive limited energy from ambient heat, light, radio, or vibrations.

In the review paper “A Review of Power Harvesting from Vibration using Piezoelectric Materials”; by Henry A. Sodano, Daniel J. Inman and Gyuhae Park; published in The Shock and Vibration Digest, Vol. 36, No. 3, May 2004 197-205, Sage Publications; discusses the process of acquiring the energy surrounding a system and converting it into usable electrical energy—termed power harvesting. The paper discuss the research that has been performed in the area of power harvesting and the future goals that must be achieved for power harvesting systems to find their way into everyday use.

Patent application WO07038157A2; titled “Energy Harvesting Using Frequency Rectification”; to Carman Gregory P. and Lee Dong G.; filed: 2006 Sep. 21 discloses an energy harvesting apparatus for use in electrical system, having inverse frequency rectifier structured to receive mechanical energy at frequency, where force causes transducer to be subjected to another frequency.

More general background and information concerning piezoelectric devices may be found in other patents and patent applications

For example:
U.S. Pat. No. 6,277,299 to Seyed
U.S. Pat. No. 5,825,386 to Ohashi
U.S. Pat. No. 4,412,148 to Kilcker
U.S. Pat. No. 5,340,510 to Bowen
U.S. Pat. No. 4,404,490 to Taylor
US 2006/118678 to Wells
US 2006/087201 to Spinelli
US 2005/0258717 to Mullen
US 2005/127677 to Luttrull,
JP2006-197704A to Mutou;
JP2005-353015A to Kokatsu;
JP10-073073A to Okawa
JP 08-098564 to Yamamoto
JP141478 to Kimura
JP2002-063685 to Tamura
EP 1,783,026 to Zoll
WO2006/053479 to Cao
CN1633008 to Cao et al.
CN 1,633,009
GB 2,389,249 to Mark Colin Porter

### SUMMARY OF THE INVENTION

The present invention relates to an energy harvesting apparatus having stack piezoelectric elements, and system, method and applications for implementation of said apparatus.

A stack of piezoelectric elements, in the form of an elongated rod divided in to segments, for generating electric energy in response to compressive stress is provided comprising: piezoelectric elements stacked one on top of the other such that electrodes of same polarity of adjacent disks are touching A holding structure, such as a screw holds the piezoelectric elements together between a top and a bottom end pieces which transfer mechanical compressive stress to the elements in the stack. The holding structure accepts shear stresses, provides preloading stress on the stack and prevents buckling of the stack under pressure. A recess in the end piece, deeper than the head of the screw, ensures that load, placed on the stack, will compress the piezoelectric elements and not on the screw.

It is an object of the current invention to provide a piezoelectric stack, in the form of an elongated rod divided in to segments, for generating electric energy in response to compressive stress comprising: a plurality of piezoelectric disks or other shapes, such as rings each having a positive and a negative electrode on their opposing faces, stacked one on top of the other such that positive electrodes of adjacent disks are touching, and negative electrodes of adjacent disks are touching; positive and negative wires connected to positive electrodes and negative electrodes respectively; a holding structure, holding said plurality of disks together; and top and bottom end pieces, in mechanical contact with the first and last disks in the stack and adopted to transfer mechanical compressive stress to said disks in said stack.

In some embodiments, inert disks or rings are added to the structure, for example to adjust for the structure's length or to be used as electrodes or to add flexibility to the structure.

In some embodiments the holding structure is a pin inserted in holes in said disks and said end pieces.

In some embodiments the piezoelectric stack further comprises at least one screw and nut combination, capable of applying preloading compressive force between said end pieces by tightening it to said pin.

In some embodiments the disks further comprising at least two grooves capable of accepting said positive and negative wires.

In some embodiments the piezoelectric stack further comprises a moisture proof cover, capable of protecting said disks.

In some embodiments the shape of said stack is substantially cylindrical.

In some embodiments the holding structure is a pipe holding said disks and said end pieces.

In some embodiments the pipe further comprises at least two internal grooves capable of accepting said positive and negative wires.

It is another object of the current invention to provide a piezoelectric generator comprising: a top and a bottom stiff load plate; a piezoelectric stack, in the form of an elongated rod divided in to segments, placed between said top and bottom load plate, said stack comprising: a plurality of piezoelectric disks, each having a positive and a negative electrode on their opposing faces, stacked one on top of the other such that positive electrodes of adjacent disks are touching, and negative electrodes of adjacent disks are touching; and positive and negative wires connected to positive electrodes and negative electrodes respectively; and at least three pins holding said top and a bottom load plate together.

In some embodiments the at least three pins holding said top and a bottom load plate together mechanically supports said stack against out of plate displacements.

In some embodiments the stack further comprises a holding structure, stabilizing said stack against out of plate displacements.

It is another object of the current invention to provide a piezoelectric block generator comprising: a block having a plurality of holes; a plurality of piezoelectric stacks, each in the form of an elongated rod divided in to segments, placed in said holes, each of said stack comprising: a plurality of piezoelectric disks, each having a positive and a negative electrode on their opposing faces, stacked one on top of the other such that positive electrodes of adjacent disks are touching, and negative electrodes of adjacent disks are touching; and positive and negative wires connected to positive electrodes and negative electrodes respectively; positive and negative cables connecting said positive and negative wires respectively; and a cover, covering said piezoelectric stacks and capable of transferring mechanical compressive stress applied to said cover to said plurality of stacks.

In some embodiments the block is made by casting.

In some embodiments the block further comprises a recess capable of holding an energy conditioning electronics, electronically connected to the positive and negative cables.

It is another object of the current invention to provide a method of constructing a block piezoelectric generator, the method comprises the steps of: mechanically connecting a plurality of piezoelectric stacks to the lower side of a cover capable of spreading compressive stress among said stacks; electrically connecting positive and negative cables to positive and negative wires of said stacks respectively; pouring curable liquid into a block-shaped mold; lowering said cover into said mold such that said stacks are embedded in said curable liquid; and letting said curable liquid harden.

In some embodiments the method of constructing a block piezoelectric generator comprises the steps of: pouring curable liquid into an upside-down block-shaped mold having a plurality of sleeves, wherein each of said sleeve is capable of snugly holding a piezoelectric stack, such that said sleeve remain empty; letting said curable liquid harden; turning said block upright; inserting a plurality of stacks to at least some of said sleeve, such that top end of each stack is slightly outside said sleeve; electrically connecting positive and negative cables to positive and negative wires of said stacks respectively; covering said block with a cover capable of spreading compressive stress among said stacks.

It is another object of the current invention to provide a system for energy harvesting comprising: a plurality of piezoelectric stacks, wherein each stack comprises: a plurality of piezoelectric disks, each having a positive and a negative electrode on their opposing faces, stacked one on top of the other such that positive electrodes of adjacent disks are touching, and negative electrodes of adjacent disks are touching; positive and negative wires connected to positive electrodes and negative electrodes respectively; a holding structure, holding said plurality of disks together; and top and bottom end pieces, in mechanical contact with the first last disks in the stack and adopted to transfer mechanical compressive stress to said disks in said stack; and positive and negative cables electrically connecting positive and negative wires of said stacks respectively.

In some embodiments the stacks are embedded in railway sleepers.

In some embodiments the system stacks are embedded under railway sleepers.

In some embodiments the stacks are embedded under railway tracks.

In some embodiments the stacks are embedded in holes drilled in a road or a pavement.

In some embodiments the stacks are under a vibrating machine.

It is yet another object of the current invention to provide a method of constructing an energy harvesting system comprising the steps of: placing a plurality of block piezoelectric generators on a foundation; and connecting electrical cables from block piezoelectric generators to a user electrical load; and covering said block piezoelectric generators, wherein each block piezoelectric generator comprises: a block having a plurality of holes; a plurality of piezoelectric stacks placed in said holes; and a cover, covering said piezoelectric stacks and capable of transferring mechanical compressive stress applied to said cover to said plurality of stacks.

In some embodiments the step of placing a plurality of block piezoelectric generators comprises placing said blocks side by side; and the step of covering said block piezoelectric generators comprises covering said generator with a cover such as asphalt, bitumen; concrete or tiles.

In some embodiments the step of placing a plurality of block piezoelectric generators comprises: digging a trench in a road; and placing said blocks side by side in said trench; and the step of covering said block piezoelectric generators comprises refilling the trench with asphalt or bitumen.

Unless otherwise defined, all technical and scientific terms used herein have the same meaning as commonly understood by one of ordinary skill in the art to which this invention belongs. Although methods and materials similar or equivalent to those described herein can be used in the practice or testing of the present invention, suitable methods and materials are described below. In case of conflict, the patent specification, including definitions, will control. In addition, the materials, methods, and examples are illustrative only and not intended to be limiting.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in the cause of providing what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

The invention is capable of other embodiments or of being practiced or carried out in various ways. Also, it is to be understood that the phraseology and terminology employed herein is for the purpose of description and should not be regarded as limiting.

In discussion of the various figures described herein below, like numbers refer to like parts. The drawings are generally not to scale. For clarity, non-essential elements were omitted from some of the drawings.

In the drawings:

FIG. 1a schematically depicts an isometric view of a piezoelectric ring element according to an exemplary embodiment of the current invention.

FIG. 1b schematically depicts a top view of the piezoelectric ring element seen in FIG. 1a according to an exemplary embodiment of the current invention.

FIG. 1c schematically depicts cross section of the piezoelectric ring element seen in FIGS. 1a and 1b according to an exemplary embodiment of the current invention.

FIGS. 1d(i) and 1d(ii) respectively depicts schematic top view cross section of the piezoelectric ring element according to another exemplary embodiment of the current invention.

FIG. 2a schematically depicts cross section view of a piezoelectric stack device using several ring elements seen in FIGS. 1a-c according to an exemplary embodiment of the current invention.

FIG. 2b schematically depicts an isometric view of a piezoelectric stack device seen in FIG. 2a according to an exemplary embodiment of the current invention.

FIG. 2c schematically depicts a top or bottom view of a piezoelectric stack device seen in FIGS. 2a-b according to an exemplary embodiment of the current invention.

FIG. 2d schematically depicts a 3D isometric view of a piezoelectric disk element according to another exemplary embodiment of the invention.

FIG. 2e schematically depicts a horizontal cross section through a stack constructed from a plurality of disks according to another exemplary embodiment of the invention.

FIG. 2f schematically depicts a vertical cross section along the line B-B seen in FIG. 2d, of a stack according to the exemplary embodiment of the current invention.

FIGS. 3(a-e) respectively depict 3D isometric view; side view; vertical cross section; top; and bottom views of a stack using ring piezoelectric elements according to yet another embodiment of the current invention.

FIG. 4a schematically depicts an isometric view of an optional piezoelectric generator using a stack device seen in FIGS. 2a-c according to an exemplary embodiment of the current invention.

FIG. 4b schematically depicts a top view of a piezoelectric generator seen in FIG. 3a according to an exemplary embodiment of the current invention.

FIG. 4c schematically depicts a side view of a piezoelectric generator seen in FIGS. 3a-b according to an exemplary embodiment of the current invention.

FIG. 4d schematically depicts a cross section view of a piezoelectric generator seen in FIGS. 3a-c according to an exemplary embodiment of the current invention.

FIG. 4e(i) to 3e(iii) schematically depict: a side view, an isometric view and a top view of a piezoelectric generator according to another exemplary embodiment of the current invention.

FIG. 5 schematically depict a top view of an implementation in a road of an energy harvesting system using piezoelectric generators seen in FIG. 2 or 3, according to an exemplary embodiment of the current invention.

FIG. 6a schematically depict a cross section view of a piezoelectric generator implementation in a railway sleeper according to an exemplary embodiment of the current invention.

FIG. 6b schematically depict a cross section view of a piezoelectric generator implementation in a railway according to other exemplary embodiments of the current invention.

FIGS. 7(a-f) schematically depict steps of constructing an energy harvesting system in a road by embedding a plurality of separate stacks according to an exemplary embodiment of the current invention.

### DESCRIPTION OF THE PREFERRED EMBODIMENTS

The present invention relates to an energy harvesting apparatus having stack piezoelectric elements, and system, method and applications for implementation of said apparatus.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. It can be applied for any surface where mechanical load can be transferred efficiently into electrical load.

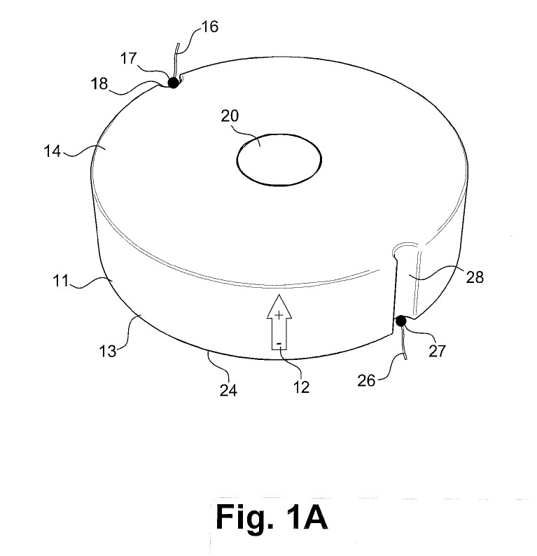

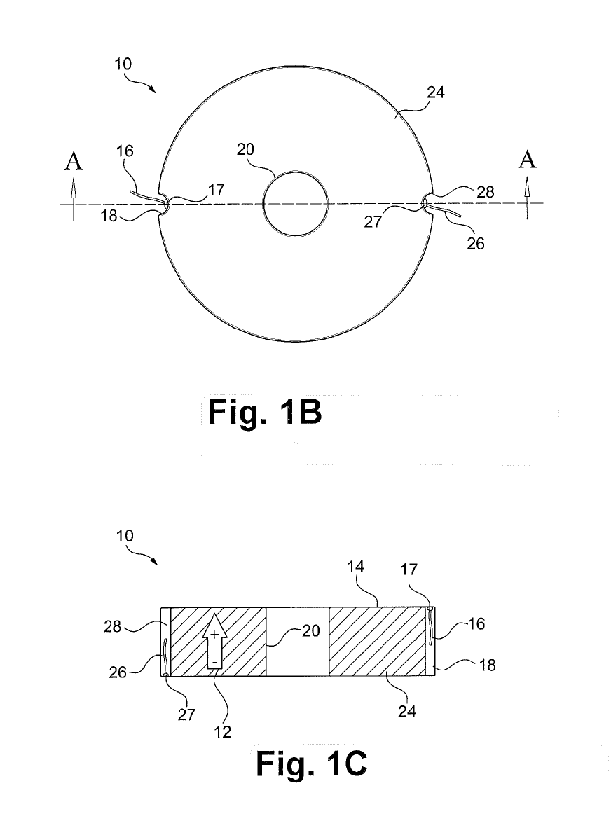

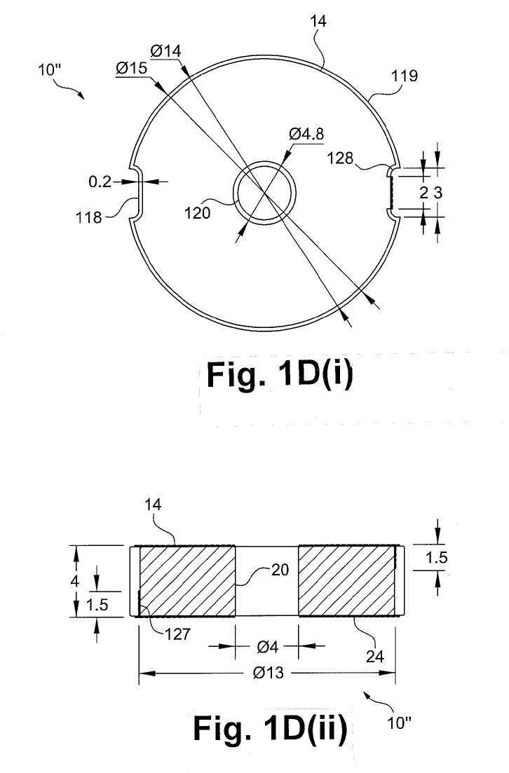

FIG. 1a schematically depicts an isometric view of a piezoelectric disk 10 according to an exemplary embodiment of the current invention.

Washer shaped bioelectric element 10 comprises a round disk, rings 11 made of piezoelectric material polled in the direction depicted by the arrow 12 such that compression axial load applied in the thickness direction, yield to compression stress, where parallel faces 13 and 14 would create a voltage due to the piezoelectric coefficient d_{3,3}. Top electrode is formed by coating the top face 14 with a conductive coating for example a conductive metal such as silver, copper or Nickel or other conducting material. Top electrode is connected to a positive wire 16 at a contact 17 located within the first optional groove 18 on the side of the disk.

Similarly, bottom electrode is formed by coating the bottom face 13 with a conductive coating for example a conductive metal such as silver, copper or Nickel. Bottom electrode is connected to a positive wire 26 at a contact 27 located within the second optional groove 28 on the side of the disk.

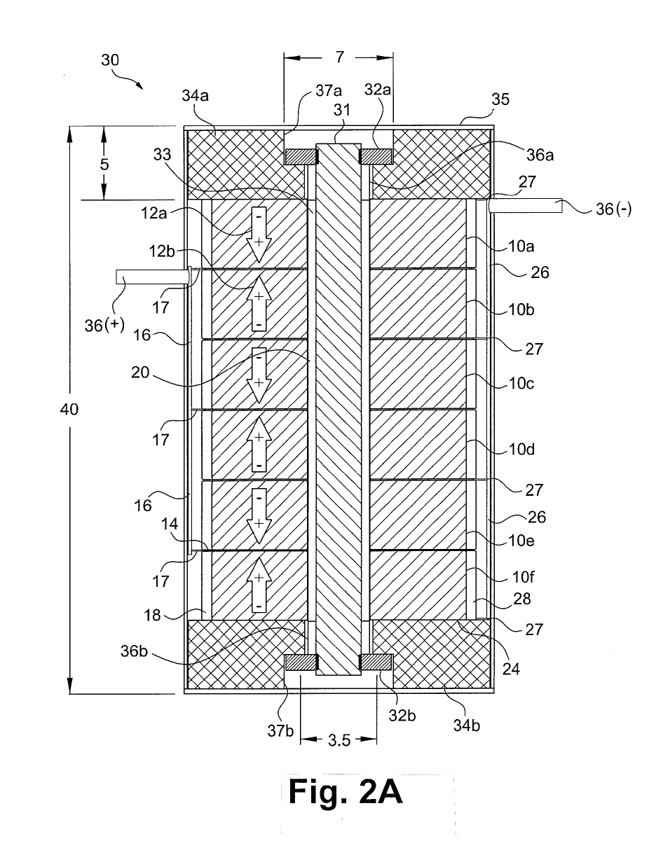

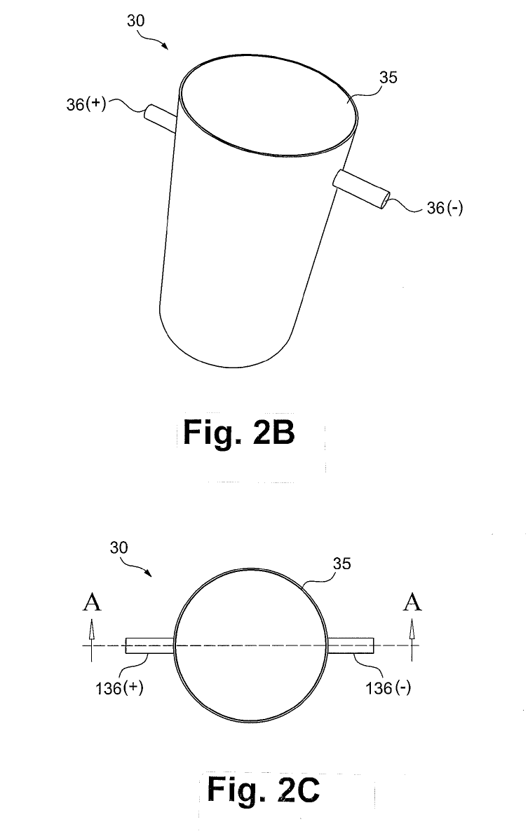

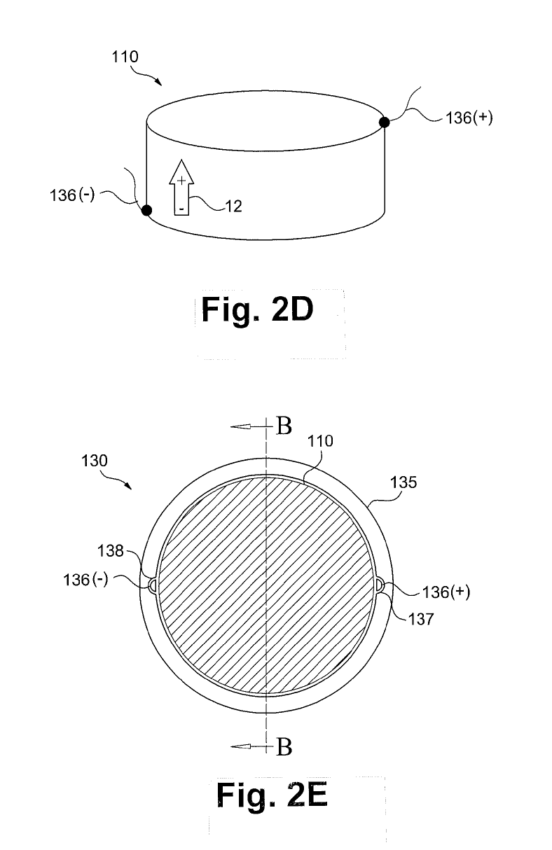

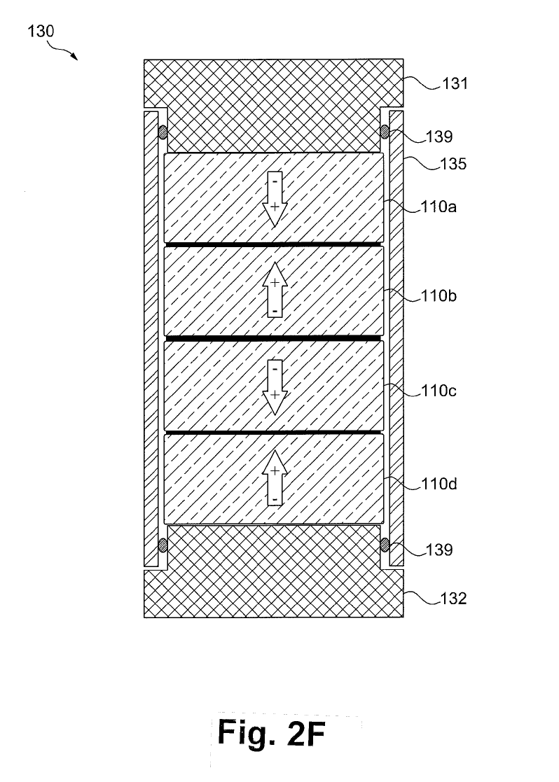

Central hole 20 is preferably at the center of disk 10. This optional hole may be used for stabilizing a stack as will be seen in FIG. 2a.

FIG. 1b schematically depicts a top view of the piezoelectric element 10 seen in FIG. 1a according to an exemplary embodiment of the current invention.

The flush central hole 20 is clearly seen. First optional groove 18 and second optional groove 28 are seen opposite to each other, however, locations of grooves, their shapes, and sizes may vary. Grooves 18 and 28 are sized so wires 16 and 26 can fit inside them. Dimensions indicated in this and all other figures should be viewed as non limiting examples.

The dashed line A-A marks the cross section plane seen in FIG. 1c.

Dimensions on this and other figures are for demonstration of one of the preferred embodiment and should not be viewed as limiting.

FIG. 1c schematically depicts cross section of the piezoelectric disk element 10 seen in FIGS. 1a and 1b according to an exemplary embodiment of the current invention. Connection 17 between wire 16 and bottom electrode 13 may be clearly seen. Similarly, Connection 27 between wire 26 and top electrode 24 may be clearly seen.

FIGS. 1d(i) and 1d(ii) respectively depicts schematic top view cross section of the piezoelectric ring element according to another exemplary embodiment of the current invention.

In this exemplary embodiment, electrodes 14 and 24 do not extend to the outer edge 119 of ring element 10″. Similarly, electrodes 14 and 24 do not extend to the inner edge 129 of the hole of ring element 10′.

However, in this exemplary embodiment, electrodes 14 and 24 extend onto the outer edge of ring element 10″ in grooves 118 and 128 respectively. These extensions may be used to connect or solder wires 16 and 26 respectively.

Note that dimensions in these figures are to be viewed as non limiting examples only.

FIG. 2a schematically depicts cross section view of a piezoelectric stack device 30 using elements seen in FIGS. 1a-c according to an exemplary embodiment of the current invention.

A plurality of piezoelectric elements 10 (in the depicted example, six such elements: 10a to 10f are seen, but number of elements may vary according to the application) are placed one on top of the other such that the poling direction as depicted by arrows 12 (for drawing clarity, only 12a and 12b are marked in the drawings) alternate.

As a result, two adjacent elements are placed such that top (positive) electrode of one element touches the positive electrode of its neighbor, and a bottom (negative) electrode of one element touches the negative electrode of its neighbor. A central pin 31, preferably having an insulator sleeve or coated by insulator 33 is inserted through the central holes 20 of the elements 10 and holds them in place. Central pin 31 prevents horizontal displacements or buckling of the piezoelectric stack thus formed from the plurality of elements 10 when compression stress is applied to it by accepting sheer stresses that may develop.

Two load transferring end pieces 34a and 34b, each having a hole 36a and 36b, and a recess 37a and 37b respectively are placed at opposite ends of the stack such that pin 31 goes through the holes 36 with its tapped end in the recesses 37. Nuts 32a and 32b respectively are screwed to each end of pin 31 thus tightening the stack by applying compression between the two load transferring end pieces 34a and 34b. The compression pressure is light and is used to ensure mechanical and electrical contact between the adjacent elements. The preloading pressure ensures that any compression stress applied between the load transferring end pieces 34a and 34b will result in electrical signal generation.

It should be noted that load transferring end pieces 34a and 34b have a diameter of at least the diameter of the piezoelectric elements, and are made of rigid material such as metal. Holes 36a and 36b are sized at least slightly larger than the diameter of pin 31, and recesses 37a and 37b are larger than nuts 32a and 32b. Thus, when pressure is applied to load transferring end pieces 34a and 34b it is transferred to the stack of piezoelectric elements 10.

Positive wires 16 connected to contacts 17 of all elements 10 are connected together and run along the first groove 18 in all elements 10 to positive out wire 36(+). Similarly, negative wires 26 from contacts 27 of from all elements 10 are connected together and run along the second groove 28 of elements 10 to negative out wire 36(−). Optionally, only one wire 16 carries the signal from the two adjacent electrodes 14 which are in electrical contact with each other. Similarly, optionally, only one wire 26 carries the signal from the two adjacent electrodes 24 which are in electrical contact with each other.

A protective cover 35 is used for covering the piezoelectric stack device 30. Protective cover 35 is preferably made of insulating material such as plastic, shrink wrap plastic or may be formed by dipping the piezoelectric stack device 30 in thermoplastic material etc. Protective cover 35 protects the internal parts of piezoelectric stack device 30 against corrosion, moisture and prevents arcing.

It should be noted that in some embodiments the stack may be sintered or glued to maintain its shape. This may be done for example using methods known in the art. Gluing or sintering may be used optionally, additionally or alternatively to applying preloading force. Gluing or sintering may be used optionally, additionally or alternatively to using a pin to maintain the shape.

Dimensions on this and other figures are for demonstration of one of the preferred embodiment and should not be viewed as limiting.

FIG. 2b schematically depicts an isometric view of a piezoelectric stack device 30 seen in FIG. 2a according to an exemplary embodiment of the current invention.

Preferably, the outer shape of piezoelectric stack device 30 is cylindrical, having an outer diameter defined by the protective cover 35. Wires 36(+) and 36(−) exit the piezoelectric stack device 30 through opening in cover 35 which makes hermetic seal to the wires to prevent moisture leak.

FIG. 2c schematically depicts a top view of a piezoelectric stack 30 device seen in FIGS. 2a-b according to an exemplary embodiment of the current invention.

The round, cylindrical shape of piezoelectric generator 30 enables easy insertion of the stack into round drilled holes.

The dashed line A-A marks the cross section plane seen in FIG. 2a.

In some embodiment, stack 30 is held together by gluing the disks together, by welding the electrodes together or by sintering the entire stack.

FIG. 2d schematically depicts a piezoelectric disk 110 element according to another embodiment of the invention.

In contrast to the disk 10 of FIGS. 1a-c, disk 110 has no central holes or grooves. Instead, wires 136(+) and 136(−), connected to top and bottom electrodes respectively are external to the perimeter of the disk.

FIG. 2e schematically depicts a horizontal cross section through a stack 130 constructed from a plurality of disks 110.

A pipe 135 holds the plurality of disks 110 and prevents sideways motion of the disks. Wires 136(+) and 136(−) runs along grooves 137 and 138 in pipe 135. The dashed line B-B marks the location of a vertical cross section plane seen in FIG. 2f.

FIG. 2f schematically depicts a vertical cross section of a stack 130 according to an exemplary embodiment of the current invention.

In this embodiment, pipe 135 holds the stack and prevents horizontal displacements or buckling of the piezoelectric stack thus formed from the plurality of elements 110 when compression stress is applied to it by accepting sheer stresses that may develop.

Two load transferring end plugs 131 and 132 accept compression forces and apply it to the stack. Preferably, preloading compression force is applied between plugs 131 and 132. Optionally, a protective coating is used for keeping moisture out. Alternatively, seals such as O ring 139 are used.

It should be noted that in some embodiments the stack may be sintered or glued to maintain its shape. This may be done for example using methods known in the art. Gluing or sintering may be used optionally, additionally or alternatively to applying preloading force. Gluing or sintering may be used optionally, additionally or alternatively to using external case to maintain the shape.

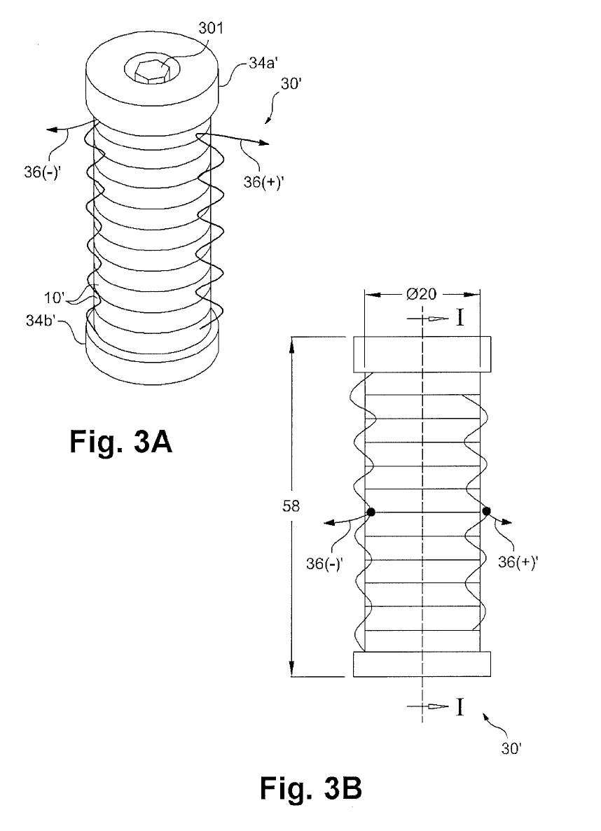

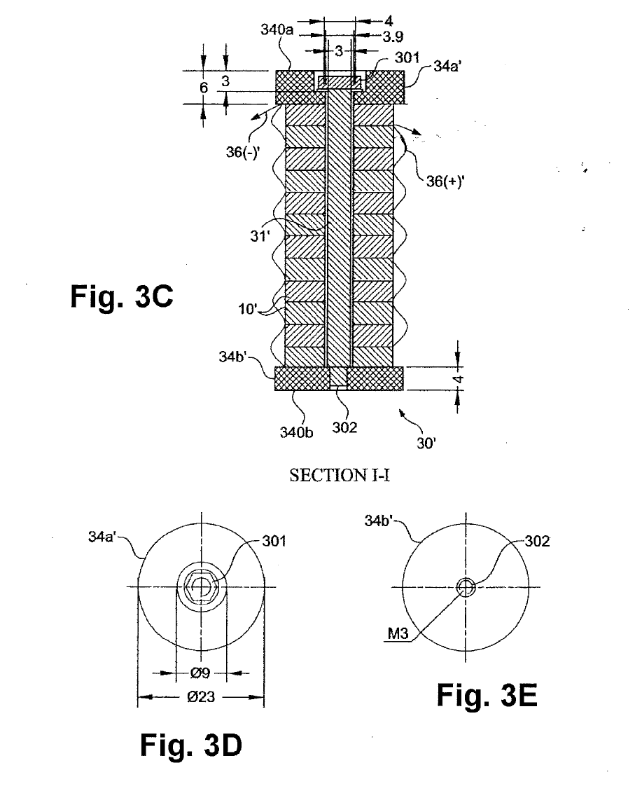

FIGS. 3(a-e) respectively depict 3D isometric view; side view; vertical cross section; top; and bottom views of a stack using ring piezoelectric elements according to yet another embodiment of the current invention.

The stack 30 depicted in FIGS. 3(a-e) is similar to the stack 30 depicted in FIGS. 1a-b and 2a-c. Thus only the main differences will be discussed herein.

In contrast to piezoelectric ring elements 10 of stack 30, piezoelectric ring elements 10′ of stack 30′ do not have groves (18 and 28 in FIG. 1a). Positive wire 36(+)′ is connected to the positive electrodes of all ring elements 10′ and continues to the energy utilization system. Similarly, negative wire 36(−)′ is connected to the positive electrodes of all ring elements 10′ and continues to the energy utilization system. Positive and negative wires 36(+)′ and 36(−)′ may be connected for example near the top of the stack (as in FIG. 3(a); near the center of the stack (as in FIG. 3(b) or at any other location.

Pin 30 is replaced with a screw 31′ having a head 301 and threaded end 302. By screwing screw 31′ into the tapped hole in bottom plate 34b′, compressive pressure is created by top plate 34a′ and 34b′. This pressure holds the stack together, provide pre-loading and ensure mechanical and electrical contact between adjacent piezoelectric elements. The head 301 of screw 31′ does not protrude above the top face 340a of plate 34a′, and the threaded end 302 of screw 31 does not protrude below the bottom face 340b of plate 34b. Thus, any compression applied to plates 34a′ and 34b′ is spread and transferred to the elements 10′ and not to screw 31′.

Cover 35 is also missing. However, in some embodiments stack 30′ may be coated with a protective cover.

In some embodiments plates such as 34a, 34b, 34a′, 34v′, 131 or 132 are made of steel.

In embodiments where number of piezoelectric elements 10, 10′, 10″ or 110 in the stack is even, top and bottom plates are in proximity to electrodes of same polarity (positive or negative, depending on the orientation of the elements). In these embodiments, the pin or pipe need not be electrically isolated from the plates, and the plates need not be electrically isolated from the electrodes, as both are at the same potential. However, the pin (or pipe) needs to be isolated from other electrodes in the stack having the opposite polarity.

Dimensions on this and other figures are for demonstration of one of the preferred embodiment and should not be viewed as limiting.

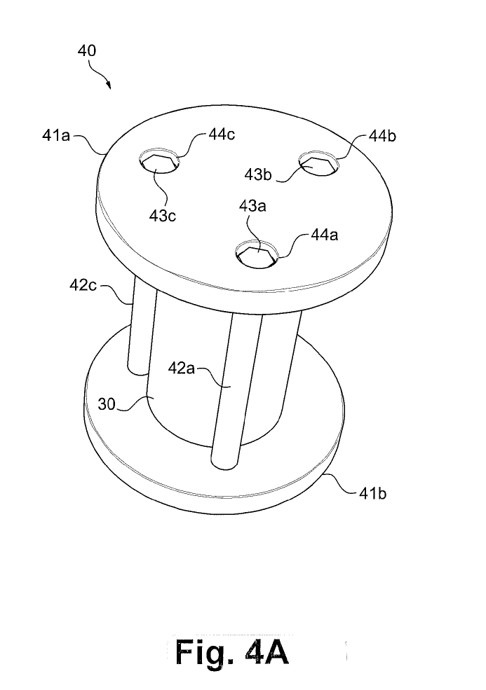

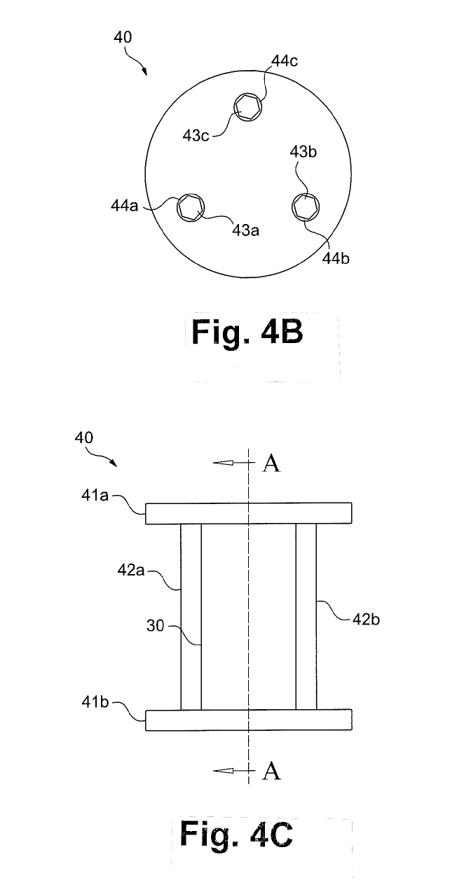

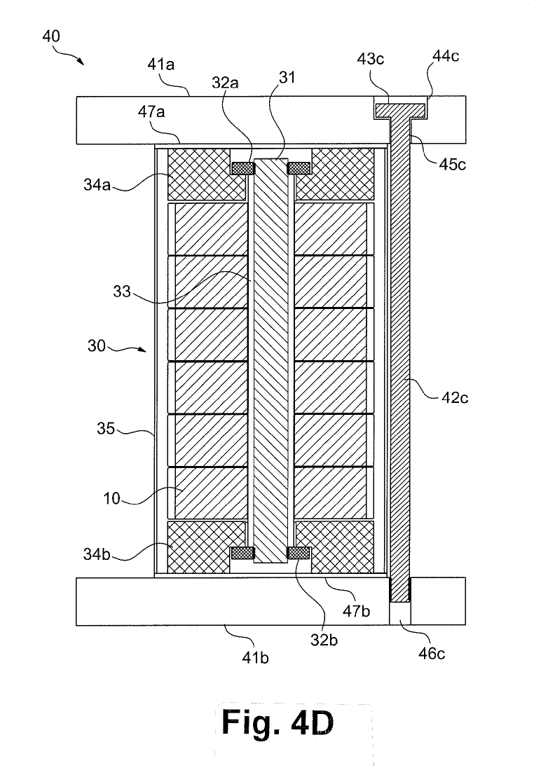

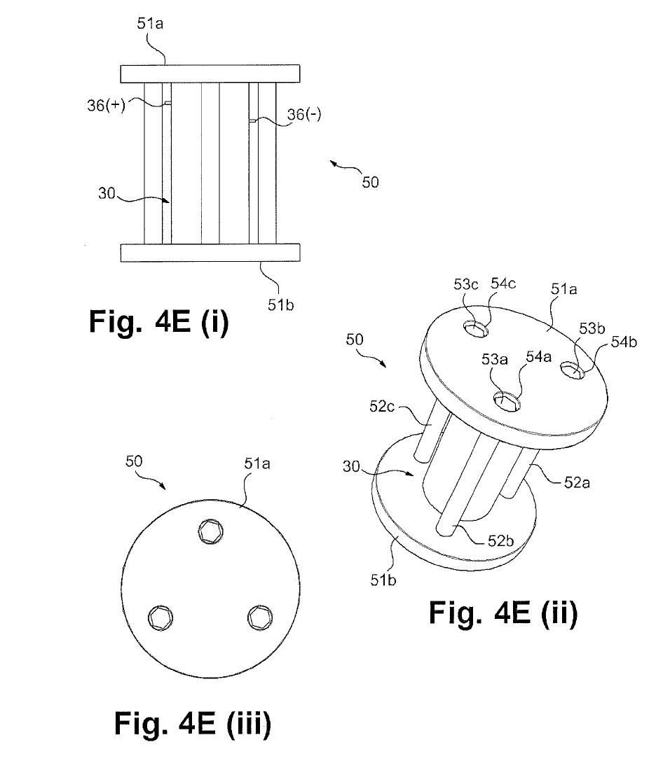

FIG. 4a schematically depicts an isometric view of a piezoelectric generator structure 40 using a stack device 30 seen in FIGS. 2a-c according to an exemplary embodiment of the current invention.

Generator 40 is made by placing a stack device 30 between two load plates 41a and 41b. The entire structure is held in place by at least three screws 42a, 42b and 42c (screw 42b is hidden from view in this drawing), having screw heads 43a to 43c respectively. Screws or guide 42a, 42b and 42c traverses plate 41a through holes in plate 41a, and heads 43a-c of screws 42a-c are within reassess 44a-c in plate 41a. Plates 41 are preferably made of rigid material such as metal or hard plastic. Thus, pressure applied to plats 41a and 41b is transferred to piezoelectric stack 30. The diameter of plates 41 is larger than the diameter of stack 30, thus enabling load concentration to the smaller diameter stack.

Screws or guide 42 are preferably placed to be in contact with the outer dimension of stack 30, thus assist pin 31 in accepting any out of plate displacements that may develop, for example due to eccentric loading. Additionally, screws 42 may also be used to apply preloading compression on stack 30.

For clarity, wires 36 were omitted from the drawings.

It should be noted that in some embodiments the stack may be sintered or glued to maintain its shape. This may be done for example using methods known in the art. Gluing or sintering may be used optionally, additionally or alternatively to applying preloading force. Gluing or sintering may be used optionally, additionally or alternatively to using external case to maintain the shape. Gluing or sintering may be used optionally, additionally or alternatively to using a pin to maintain the shape.

FIG. 4b schematically depicts a top view of a piezoelectric generator 40 seen in FIG. 3a according to an exemplary embodiment of the current invention.

FIG. 4c schematically depicts a side view of a piezoelectric generator 40 seen in FIGS. 3a-b according to an exemplary embodiment of the current invention.

The dashed line A-A marks the cross section plane seen in FIG. 3d.

FIG. 4d schematically depicts a cross section view along the A-A plane of FIG. 3c, of a piezoelectric generator 40 seen in FIGS. 3a-c according to an exemplary embodiment of the current invention.

In this figure, the holes 45c in plate 41a, for screw 42c is clearly seen. Screw 42c is screwed to tapped hole 46c in pate 41b by rotating its head 43c within recess 44c.

Optional centering indentations 47a and 47b in plates 41a and 41b respectively are sized to fit stack 30.

When compression is applied between plates 41a and 41b, the stress is transferred to stress load transferring end pieces 34a and 34b 34a and from it to the piezoelectric 10 in stack 30.

FIGS. 4e(i) 4e(ii) and 4e(iii) respectively schematically depict: a side view, an isometric view and a top view of a piezoelectric generator 50 according to another exemplary embodiment of the current invention.

Generator 50 is similar in construction to generator 40, however, in contrast to piezoelectric generator 50, screws 52a to 52c which connect plates 51a and 51b, do not touch stack 30. Just as in generator 40, screw heads 53a-c are within recesses 54a-c in plate 51a.

In FIG. 3e(i), wires 36(+) and 36(−) may be seen.

It should be noted that in some embodiments the stack may be sintered or glued to maintain its shape. This may be done for example using methods known in the art. Gluing or sintering may be used optionally, additionally or alternatively to applying preloading force. Gluing or sintering may be used optionally, additionally or alternatively to using external case to maintain the shape. Gluing or sintering may be used optionally, additionally or alternatively to using a pin to maintain the shape.

In some embodiments, a plurality of stacks is used in generator 50. For example three or four stacks 30 or 130 are placed between plates 41a and 41b. In these embodiments, screws 41 apply a preloading force on all the stacks.

It should be noted that the round shape of piezoelectric elements 10, 10′. 10″ and 110 is one of the preferred embodiments. Other shapes may be used, for example square or hexagonal or any other shape. Round shape of a stack may be achieved with non-round elements, for example by having round end plates 34, 35 or round pipe 135. In some embodiments round cover 35 or round pipe 155 may have non-round internal hole matching the shape of the piezoelectric elements.

However, stacks with shapes other than round may be used within the general scope of the current invention.

In some embodiments round generators 40 or 50 may be constructed with a stack having shape different than cylindrical by using round plates 41 and 51.

However generators with shapes other than round may be used within the general scope of the current invention.

In FIGS. 4a-e, one stack per generator is seen. However, generators with more than one stack may be used within the general scope of the current invention. Optionally, stacks are symmetrically placed between plates 41 or 51.

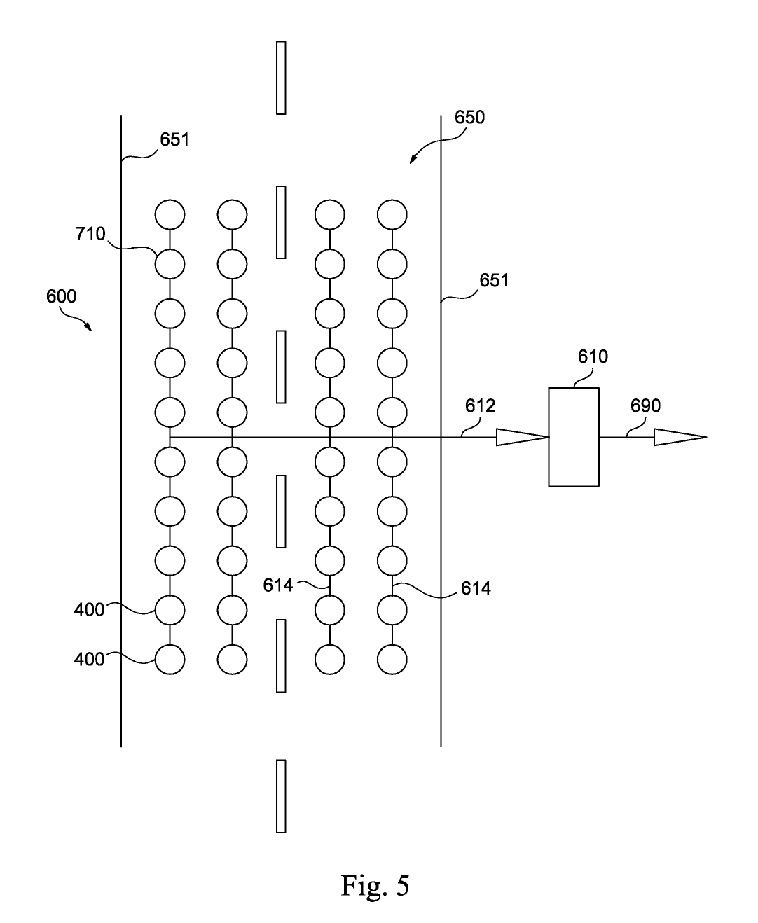

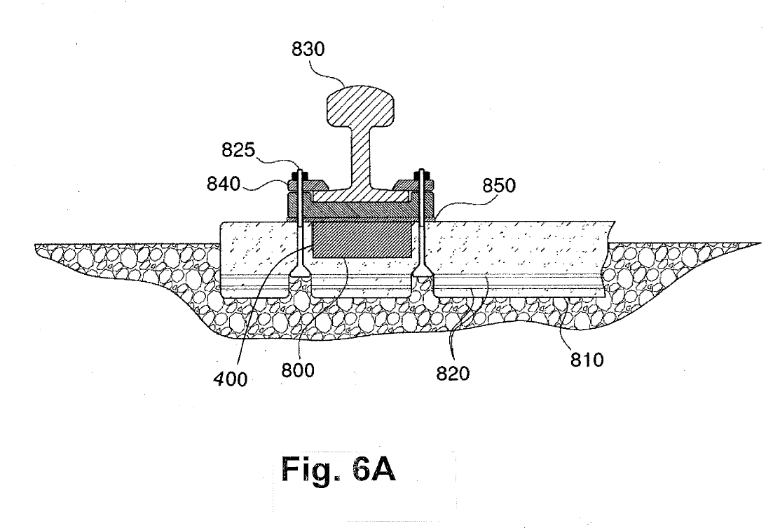

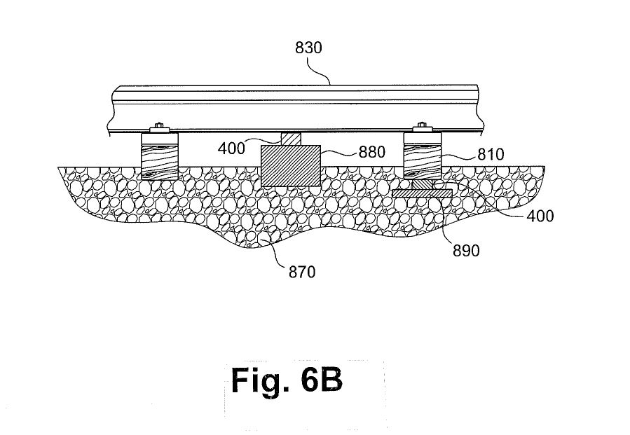

FIGS. 5 and 6 schematically depict some exemplary uses for the already disclosed stacks and generators. It should be clear that the stacks and generators according to the current invention may be used in other applications where conversion of compressive mechanical energy is to be converted to useful electrical energy.

FIG. 5 schematically depict a top view of an implementation in a road, of an energy harvesting system 600 using energy harvesting device 800 which could be one of: stack 30, generator 40 or generator 50 seen in FIG. 2 or 3, according to an exemplary embodiment of the current invention.

In the depicted example, two lanes road 650 having curbs 651 is embedded with a plurality of round energy harvesting device 400, each inserted in a round hole 710, preferably located were wheels of traveling vehicles are most likely to pass. Connecting cables 614 and 612, transfer generated electrical energy to a control unit 610 for storage or for delivery to energy user such as electrical main grid vial cable 690.

Preferably, Connecting cables 614 and 612 are also embedded beneath the surface of road 650.

FIG. 6a schematically depict a cross section view of an application of energy harvesting device 400 which could be one of: stack 30; stack 130; generator 40; generator 50; or block generator 60, implemented in a railway sleeper 810, according to an exemplary embodiment of the current invention.

In this cross section, energy harvesting device 400 is seen placed in a sleeper 810. The recess 800 in sleeper 810 preferably sized such that the internal recess acts as a box and mount 840 and elastomeric layer 850 acts as cover.

FIG. 6b schematically depict a cross section view of an application of energy harvesting device 400 which could be one of: stack 30; stack 130; generator 40; generator 50; or block generator 60, implemented in a railway, according to other exemplary embodiments of the current invention.

In this cross section, energy harvesting device 400 is seen placed for example under sleeper 810 within the foundation layer 870. Preferably a block 890, placed under energy harvesting device 400 is used for supplying counter force to the compression force of sleeper 830 when a train is passing.

In this cross section, energy harvesting device 400 is also seen placed for example under rail 830. Preferably a block 880, placed under energy harvesting device 400 is used for supplying counter force to the compression force of rail 830 when a train is passing.

When a train traverses along rail 830, stress caused by the train's weight it transferred via rail 830, mount 840 and elastomeric layer 850 and compresses on energy harvesting device 400, causing charge to be generated. Depth of recess 800 in sleeper 810 is limited by metal reinforcement cables or bars 820 in sleeper and design conclusions 810. This depth limits the length of the energy harvesting device 400. However, Sleeper 810 may be redesigned to allow deeper recesses. Similarly, width of for energy harvesting device 400 in sleeper 810 is limited by the distance between screws 825 and design conclusions which hold mount 840 to sleeper 810; however, sleeper 810 may be redesigned to allow wider or narrower recesses.

Preferably recesses 800 are preferably round and may be easily drilled in a preexisting sleeper. Alternatively, recesses 800 may be created when a concrete sleeper is molded. Round recess 800 is preferably sized so that inserted stack 30, generator 40 or 60 is snugly fits in it such that side walls of recess 800 are used to carry and accept some of the shear stress that may be developed due to train vibrations.

It should be noted that cables (not seen in FIG. 6 for clarity) collects the generated electric power and relay it to be used.

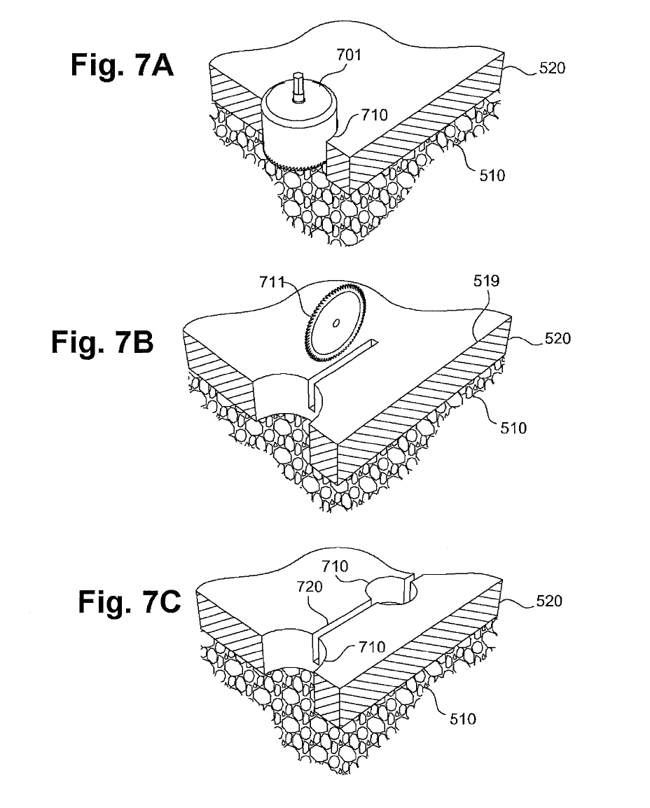

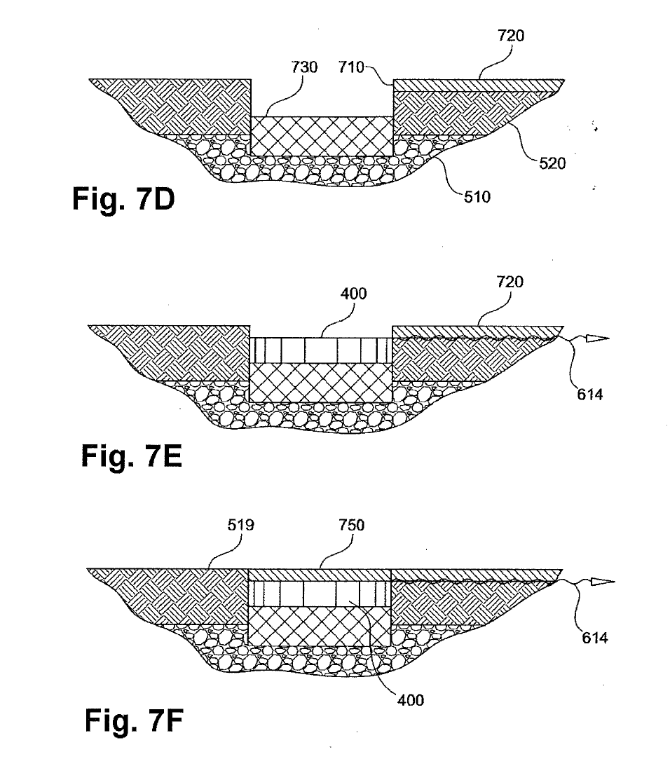

FIG. 7 schematically depict steps of constructing an energy harvesting system 600 by embedding a plurality of round energy harvesting devices 800 according to an exemplary embodiment of the current invention. It is noted that figures are generally not to scale.

FIG. 7(a) schematically depicts drilling, in a road, holes 710 for embedding round stacks or generators (For example 30; 130; 40; or 50), preferably using a cup drill 701. Drilling circular holes in a road is easier than cutting rectangular holes. Drilling hole 710 in asphalt layer 520 having an upper surface 519 which is deposited over a foundation layer 510, may be done using standard roadwork equipment, for example cup drill 701 may be used to remove a cylindrical core from the road leaving a cylindrical hole 710.

FIG. 7(b) schematically depicts cutting slits 720 in the road's asphalt layer 520, for embedding connecting cable 614, preferably using a disk saw 711.

Optionally, slits 720 and holes 710 are made only part way into asphalt layer 520. However any of slits 720 and holes 710 may be made all the way to or into foundation layer 510.

FIG. 7(c) schematically depicts the prepared holes and slits. In some embodiments, slits 720 is missing. In this embodiment, connecting cables are laid on the surface of the road and a layer of asphalt is poured over it. This method is useful when resurfacing a road. The method comprises the step of: removing the top layer of the road by abrasion; drilling the holes; installing generators in the holes; laying the cables; and resurfacing the road with a top layer of asphalt. The method may be preferred as it does not require cutting the slots, thus saving time and cost and prevents weakening the road by the slots.

FIG. 7(d) schematically depicts optional stage of pouring a reinforcing layer 730, preferably made of concrete at the bottom of the drilled hole 710. The optional reinforcement layer 730 acts as sturdy foundation for the round multilayer modular generator 400 to be placed in hole 710 and may be used to ensure desired depth of hole 710 which may not be easily drilled to the required accuracy.

FIG. 7(e) schematically depicts the stage of laying the round energy harvesting device 400 which could be one of: stack 30, generator 40 or generator 50 in drilled hole 710 over optional reinforcement 730, and placing the connecting cables 614 in the cut slit 720.

FIG. 7(f) schematically depicts the stage of refilling the drilled holes and the cut slits, preferably with asphalt or bitumen 750, thus embedding round multilayer modular generator 400 and cables 614 of system 600 below the surface 519 of the road.

It should be noted that in some embodiments the stack may be sintered or glued to maintain its shape. This may be done for example using methods known in the art. Gluing or sintering may be used optionally, additionally or alternatively to applying preloading force. Gluing or sintering may be used optionally, additionally or alternatively to using external case to maintain the shape. Gluing or sintering may be used optionally, additionally or alternatively to using a pin to maintain the shape.

It should be noted that round generators used in the embodiments depicted in FIGS. 7a-f may be stacks such as stacks 30, 130 or other stacks known in the art; generators such as generators 40, 50, or generators using a plurality of stack or other generators known in the art.

It also should be noted that in some applications, standard piezoelectric stacks and generator as known in the art may replace the stacks and generators depicted herein.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the various embodiments of the invention without departing from their scope. While the dimensions and types of materials described herein are intended to define the parameters of the various embodiments of the invention, the embodiments are by no means limiting and are exemplary embodiments. Many other embodiments will be apparent to those of skill in the art upon reviewing the above description. The scope of the various embodiments of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects.

Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

This written description uses examples to disclose the various embodiments of the invention, including the best mode, and also to enable any person skilled in the art to practice the various embodiments of the invention, including making and using any devices or systems and performing any incorporated methods. The patentable scope of the various embodiments of the invention is defined by the claims, and may include other examples that occur to those skilled in the art. Such other examples are intended to be within the scope of the claims if the examples have structural elements that do not differ from the literal language of the claims, or if the examples include equivalent structural elements with insubstantial differences from the literal languages of the claims.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

What is claimed:

1. A piezoelectric stack, for generating electric energy in response to compressive stress comprising:
a plurality of ring shaped piezoelectric elements, each having a positive and a negative electrode, stacked one on top of the other such that positive electrodes of adjacent elements are touching, and negative electrodes of adjacent disks are touching;
positive and negative wires connected to positive electrodes and negative electrodes respectively;
a top end piece having a recess, and a bottom end piece, wherein said end pieces are in mechanical contact with first last elements respectively in the stack, and are capable of transferring mechanical compressive stress applied them to said piezoelectric elements in said stack, thus casing generation of electrical signal by said elements; and
a pin holding structure having a head and a threaded end inserted in holes in said piezoelectric elements and said end pieces such that its head is below the top face of said top end piece, and the end of its threaded end is below the lower face of said bottom end piece.

2. The piezoelectric stack of claim 1 wherein said threaded end of said pin is screwed into a tapped hole in said bottom end piece such that preloading compressive force is applied between said end pieces.

3. The piezoelectric stack of claim 1 and further comprising at least one nut, sized to fit within a recess in said bottom end piece, and capable of applying preloading compressive force between said end pieces by tightening it to said pin.

4. The piezoelectric stack of claim 1 herein the head of said pin comprises a nut, sized to fit within said recess in said top end piece, and capable of applying preloading compressive force between said end pieces by tightening it to said pin.

5. The piezoelectric stack of claim 1 wherein said piezoelectric elements further comprising at least two grooves capable of accepting said positive and negative wires.

6. The piezoelectric stack of claim 1 and further comprising a moisture proof cover, capable of protecting said piezoelectric elements.

7. The piezoelectric stack of claim 1 wherein shape of said stack is substantially cylindrical.

8. A piezoelectric stack, in the form of a elongated rod divided into segments, for generating electric energy in response to compressive stress comprising:
a plurality of disk shaped piezoelectric elements, each having a positive and a negative electrode, stacked one on top of the other such that positive electrodes of adjacent elements are touching, and negative electrodes of adjacent disks are touching;
positive and negative wires connected to positive electrodes and negative electrodes respectively;
a top end piece having a recess, and a bottom end piece, wherein said end pieces are in mechanical contact with first last elements respectively in the stack, and are capable of transferring mechanical compressive stress applied them to said piezoelectric elements in said stack, thus casing generation of electrical signal by said elements; and
a pipe holding structure, holding said piezoelectric elements and said end pieces.

9. The piezoelectric stack of claim 8 wherein said pipe further comprising at least two internal grooves capable of accepting said positive and negative wires.

10. A piezoelectric generator comprising:
a top and a bottom load plate;
a piezoelectric stack in the form of an elongated rod divided into segments, placed between said top and bottom load plate, said stack comprising:
a plurality of piezoelectric elements, each having a positive and a negative electrode on their opposing faces, stacked one on top of the other such that positive electrodes of adjacent disks are touching, and negative electrodes of adjacent piezoelectric elements are touching; and
positive and negative wires connected to positive electrodes and negative electrodes respectively; and
at least three pins holding said top and a bottom load plate together.

11. The piezoelectric generator of claim 9 wherein said at least three pins holding said top and a bottom load plate together mechanically supports said stack against out of plate displacements.

12. The piezoelectric generator of claim 10 wherein said stack further comprises a holding structure, stabilizing said stack against out of plate displacements.

13. A system for energy harvesting comprising:
a plurality of piezoelectric stacks, each in the form of an elongated rod divided into segments, wherein each stack comprises:
a plurality of ring shaped piezoelectric elements, each having a positive and a negative electrode, stacked one on top of the other such that positive electrodes of adjacent elements are touching, and negative electrodes of adjacent disks are touching;
positive and negative wires connected to positive electrodes and negative electrodes respectively;
a top end piece having a recess, and a bottom end piece, wherein said end pieces are in mechanical contact with first last elements respectively in the stack, and are capable of transferring mechanical compressive stress applied them to said piezoelectric elements in said stack, thus casing generation of electrical signal by said elements; and
a pin holding structure having a head and a threaded end inserted in holes in said piezoelectric elements and said end pieces such that its head is below the top face of said top end piece, and the end of its threaded end is below the lower face of said bottom end piece.

14. The system of claim 13 wherein said stacks are embedded in holes drilled in a road or a pavement.

15. The system of claim 13 wherein said stacks are embedded in railway sleepers.

16. The system of claim 13 wherein said stacks are embedded under railway sleepers.

17. The system of claim 13 wherein said stacks are embedded under railway tracks.

18. The system of claim 13 wherein said stacks are under a vibrating machine.
